(19) United States
(12) Patent Application Publication
(10) Pub. No.: US 2025/0174284 A1
(43) Pub. Date: May 29, 2025

(54) MEMORY DEVICE AND METHOD OF OPERATING THE SAME

(71) Applicant: SK hynix Inc., Icheon-si Gyeonggi-do (KR)

(72) Inventors: Sung Ho KIM, Icheon-si Gyeonggi-do (KR); Jaeseong KIM, Icheon-si Gyeonggi-do (KR); Min Sang PARK, Icheon-si Gyeonggi-do (KR); Gil Bok CHOI, Icheon-si Gyeonggi-do (KR)

(73) Assignee: SK hynix Inc., Icheon-si Gyeonggi-do (KR)

(21) Appl. No.: 18/665,146

(22) Filed: May 15, 2024

(30) Foreign Application Priority Data
Nov. 28, 2023 (KR) 10-2023-0167993

(51) Int. Cl. G11C 16/34

(52) U.S. Cl. CPC G11C 16/3413

(57) ABSTRACT

The present technology relates to a memory device and a method of operating the same. The memory device includes a plurality of memory blocks each including a plurality of memory cells, peripheral circuits configured to perform a background operation and an overwrite operation on a selected memory block among the plurality of memory blocks, and control logic configured to control the peripheral circuits to perform the background operation and the overwrite operation, and the control logic controls the peripheral circuits to perform the overwrite operation including increasing a threshold voltage of the plurality of memory cells of the selected memory block to at least a predetermined threshold voltage value based on the quantity of valid data stored in the selected memory block.

### CROSS-REFERENCE TO RELATED APPLICATION

The present application claims priority under 35 U.S.C. § 119(a) to Korean patent application number 10-2023-0167993 filed on Nov. 28, 2023, in the Korean Intellectual Property Office, the entire disclosure of which application is incorporated herein by reference.

### BACKGROUND

### 1. Technical Field

The present disclosure relates to an electronic device, and particularly to a memory device and a method of operating the same.

### 2. Related Art

A write speed and a read speed of a nonvolatile memory device are relatively slow, but the nonvolatile memory device maintains storage data even when power is cut off. Therefore, the nonvolatile memory device is typically used to store data to be maintained regardless of whether power is supplied. Examples of nonvolatile memory devices includes a read only memory (ROM), a mask ROM (MROM), a programmable ROM (PROM), an erasable programmable ROM (EPROM), an electrically erasable programmable ROM (EEPROM), a flash memory, a phase change random access memory (PRAM), a magnetic RAM (MRAM), a resistive RAM (RRAM), a ferroelectric RAM (FRAM), and the like. The flash memory is classified as a NOR type or a NAND type.

Flash memory has an advantage of RAM that freely programs and erases data and an advantage of ROM that preserves stored data even when power is cut off. Flash memory is widely used as a storage medium of portable electronic devices such as a digital camera, a personal digital assistant (PDA), and an MP3 player.

### SUMMARY

According to an embodiment of the present disclosure, a memory device includes a plurality of memory blocks each including a plurality of memory cells, peripheral circuits configured to perform a background operation and an overwrite operation on a selected memory block among the plurality of memory blocks, and control logic configured to control the peripheral circuits to perform the background operation and the overwrite operation, and the control logic controls the peripheral circuits to perform the overwrite operation including increasing a threshold voltage of the plurality of memory cells of the selected memory block to at least a predetermined threshold voltage value based on the quantity of valid data stored in the selected memory block.

According to an embodiment of the present disclosure, a method of operating a memory device includes establishing the quantity of valid data stored in a selected memory block, performing a copyback operation on the selected memory block when the quantity of valid data is less than a predetermined value, and performing an overwrite operation on selected memory cells corresponding to an erase state, or the erase state and at least one program state, among memory cells included in the selected memory block.

According to an embodiment of the present disclosure, a method of operating a memory device includes establishing a quantity of valid data stored in a selected memory block on which a background operation is performed, identifying the selected memory block as an overwrite operation object memory block based on the quantity of valid data, performing a copyback operation including storing, in a target memory block, the valid data stored in the selected memory block, and performing an overwrite operation including increasing a threshold voltage of selected memory cells corresponding to an erase state, or the erase state and at least one program state, among memory cells included in the selected memory block to at least a predetermined threshold voltage value after the copyback operation.

According to an embodiment of the present disclosure, a method includes establishing a quantity of valid data stored in a first memory block of a plurality of memory blocks; when the quantity of valid data is less than a predetermined value, performing a copyback operation including storing, in a second memory block of the plurality of memory blocks, the valid data stored in the first memory block; and performing an overwrite operation including increasing a threshold voltage of a plurality of memory cells of the first memory block to at least a predetermined threshold voltage value based on the quantity of valid data stored in the first memory block.

### BRIEF DESCRIPTION OF THE DRAWINGS

FIG. 1 is a diagram illustrating a memory system according to an embodiment of the present disclosure.

FIG. 2 is a diagram illustrating a memory device according to an embodiment of the present disclosure.

FIG. 3 is a diagram illustrating an overwrite manager according to an embodiment of the present disclosure.

FIG. 4 is a diagram illustrating a memory block according to an embodiment of the present disclosure.

FIG. 5 is a diagram illustrating an embodiment of a memory block configured in three-dimensions.

FIG. 6A, FIG. 6B, FIG. 6C, FIG. 6D, and FIG. 6E are diagrams illustrating a threshold voltage decrease phenomenon of a memory cell by a hole existing in a region between memory cells.

FIG. 7 is a diagram illustrating a threshold voltage distribution according to a retention characteristic decrease of programmed memory cells.

FIG. 8 is a flowchart illustrating a method of operating a memory device according to an embodiment of the present disclosure.

FIG. 9A is a diagram illustrating a threshold voltage distribution of memory cells during an overwrite operation of a memory device according to an embodiment of the present disclosure.

FIG. 9B is a diagram illustrating a threshold voltage distribution of memory cells during an overwrite operation of a memory device according to another embodiment of the present disclosure.

FIG. 10 is a diagram illustrating another embodiment of the memory system including the memory device.

FIG. 11 is a diagram illustrating another embodiment of the memory system including the memory device.

FIG. 12 is a diagram illustrating another embodiment of the memory system including the memory device.

FIG. 13 is a diagram illustrating another embodiment of the memory system including the memory device.

### DETAILED DESCRIPTION

Specific structural or functional descriptions of embodiments according to the concepts that are disclosed in the present specification or application are examples that describe the embodiments according to the concepts of the present disclosure. The embodiments according to the concepts of the present disclosure may be carried out in various forms and should not be construed as being limited to the embodiments described in the present specification or application.

Various embodiments of the present disclosure are described with reference to the accompanying drawings to describe in detail sufficient to allow those of ordinary skill in the art to easily implement the technical aspects of the present disclosure.

An embodiment of the present disclosure provides a memory device and a method of operating the memory device capable of improving a retention characteristic of the memory device. According to the present disclosure, a retention characteristic of memory cells may be improved by performing an overwrite operation on a memory block when the quantity of valid data is less than a predetermined value.

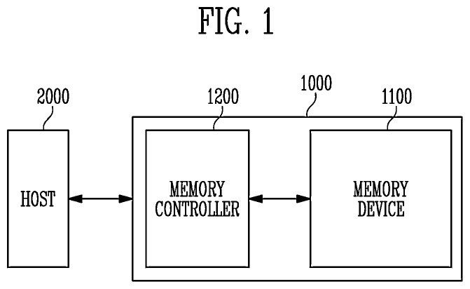

FIG. 1 is a diagram illustrating a memory system according to an embodiment of the present disclosure.

Referring to FIG. 1, under control of a host 2000, the memory system 1000 includes a memory device 1100 in which data is stored, and a memory controller 1100 that controls the memory device 1100.

The host 2000 communicates with the memory system 1000 using an interface protocol such as a peripheral component interconnect-express (PCI-E), an advanced technology attachment (ATA), a serial ATA (SATA), a parallel ATA (PATA), or a serial attached SCSI (SAS). In addition, the interface protocols between the host 2000 and the memory system 1000 are not limited to the above-described examples, and may be one of various other interface protocols such as universal serial bus (USB), a multi-media card (MMC), enhanced small disk interface (ESDI), and integrated drive electronics (IDE).

The memory controller 1200 controls an overall operation of the memory system 1000 and controls data exchange between the host 2000 and the memory device 1100. For example, the memory controller 1200 programs or reads data by controlling the memory device 1100 according to a request received from the host 2000. For example, the memory device 1100 may include a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), or a flash memory. The memory controller 1200 may control the memory device 1100 to autonomously perform background operations regardless of the request of the host 2000. For example, the memory controller 1200 may control the memory device 1100 to perform read reclaim, garbage collection, or read refresh operations.

The memory device 1100 performs a program operation, a read operation, an erase operation, and a background operation under control of the memory controller 1200.

The memory device 1100 performs an overwrite operation on a selected memory block when the quantity of valid data among data programmed in the selected memory block is less than a predetermined value or when valid data is not stored in the selected memory block. For example, when the quantity of valid data among the data programmed in the selected memory block is less than the predetermined value, the memory device 1100 performs the overwrite operation on the selected memory block after performing a copyback operation including reading program valid data from the selected memory block and programming the program valid data in another memory block. When valid data is not stored among the data programmed or stored in the selected memory block, the memory device 1100 performs the overwrite operation on the selected memory block without performing the copyback operation. The overwrite operation comprises, for example, an operation including increasing a threshold voltage of memory cells corresponding to an erase state, or the erase state and at least one program state, among memory cells included in the selected memory block to at least a predetermined threshold voltage value or greater than or equal to a predetermined threshold voltage value. The at least one program state may be a program state in which a threshold voltage distribution is relatively low among a plurality of program states. A predetermined value includes a value that may be determined in advance or when the value is used in a process or an algorithm. The value may be determined when the process or the algorithm starts or may be determined during a period while the process or the algorithm is executed.

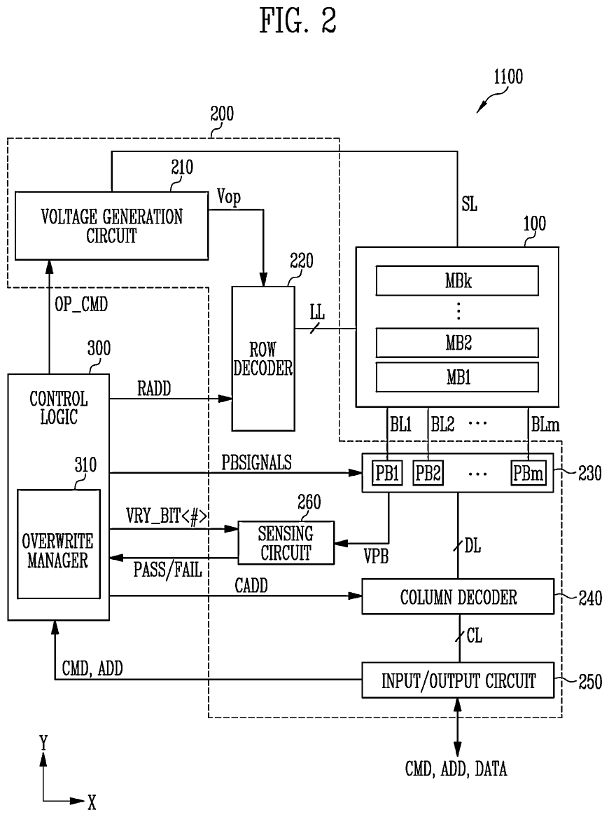

FIG. 2 is a diagram illustrating the memory device, for example, as shown in FIG. 1.

Referring to FIG. 2, the memory device 1100 includes a memory cell array 100 in which data is stored. The memory device 1100 includes peripheral circuits 200 configured to perform a program operation that stores data in the memory cell array 100, a read operation that outputs the stored data, and an erase operation that erases the stored data.

The memory device 1100 includes control logic 300 that controls the peripheral circuits 200 under control of the memory controller 1200 of FIG. 1.

The memory cell array 100 includes a plurality of memory blocks MB1 through MBk (where k is a positive integer). Local lines LL and bit lines BL1 through BLm (where m is a positive integer) are connected to each of the memory blocks MB1 through MBk. For example, the local lines LL include a first select line, a second select line, and a plurality of word lines arranged between the first select line and the second select line. The local lines LL may include dummy lines arranged between the first select line and the word lines and between the second select line and the word lines. For example, the first select line may be a source select line, and the second select line may be a drain select line. For example, the local lines LL include the word lines, the drain select line, the source select line, and source lines SL. For example, the local lines LL may include pipelines. According to an embodiment of the present disclosure, the word lines may be divided into a plurality of groups.

The local lines LL are connected to the memory blocks MB1 through MBk, and the bit lines BL1 through BLm are commonly connected to the memory blocks MB1 through MBk. The memory blocks MB1 through MBk may be implemented in a two-dimensional or three-dimensional structure. For example, pages may be arranged in a direction parallel to or horizontal to a substrate in memory blocks of a two-dimensional structure. For example, the pages may be arranged in a direction vertical to the substrate in memory blocks of a three-dimensional structure.

The peripheral circuits 200 are configured to perform the program operations, the read operations, and the erase operations on a selected memory block under control of the control logic 300. In addition, the peripheral circuits 200 are configured to perform the copyback operation including moving and storing the valid data stored in the selected memory block among the plurality of memory blocks MB1 through MBk included in the memory cell array 100 to another memory block and the overwrite operation including increasing the threshold voltage of the memory cells included in the selected memory block to at least a predetermined threshold voltage value. For example, the predetermined threshold voltage value may be greater than 0V.

For example, the peripheral circuits 200, under the control of the control logic 300, supply a verify voltage and a pass voltage to a first select line, a second select line, and the word lines, selectively discharge the first select line, the second select line, and the word lines, and verify memory cells connected to a selected word line among the word lines. For example, the peripheral circuits 200 may include a voltage generation circuit 210, a row decoder 220, a page buffer group 230, a column decoder 240, an input/output circuit 250, and a sensing circuit 260.

The voltage generation circuit 210 generates various operation voltages Vop used in the program operations, the read operations, and the erase operations in response to an operation signal OP-CMD. The voltage generation circuit 210 selectively discharges the local lines LL in response to the operation signal OP-CMD. For example, the voltage generation circuit 210 generates a program voltage, the verify voltage, the pass voltage, a turn-on voltage, a read voltage, a first erase voltage, a source line voltage, and the like under control of the control logic 300.

The row decoder 220 transfers or applies the operation voltages Vop to the local lines LL connected to the selected memory block in response to receiving a row address RADD.

The page buffer group 230 includes a plurality of page buffers PB1 through PBm connected to the bit lines BL1 to BLm, respectively. The page buffers PB1 through PBm operate in response to receiving page buffer control signals PBSIGNALS. For example, the page buffers PB1 through PBm temporarily store data received through the bit lines BL1 through BLm or sense voltages or currents of the bit lines BL1 through BLm during the read operation or a verify operation.

The column decoder 240 transmits data between the input/output circuit 250 and the page buffer group 230 in response to receiving a column address CADD. For example, the column decoder 240 exchanges data with the page buffers PB1 through PBm through data lines DL or exchanges data with the input/output circuit 250 through column lines CL.

The input/output circuit 250 transmits a command CMD and an address ADD received from the memory controller 1200 of FIG. 1 to the control logic 300 and exchanges data DATA with the column decoder 240.

During the read operation or the verify operation, the sensing circuit 260 generates a reference current in response to receiving an allowable bit VRY-BIT<#>, compares a sensing voltage VPB received from the page buffer group 230 with a reference voltage generated by the reference current, and outputs a pass signal PASS or a fail signal FAIL as a result of the comparison.

The control logic 300 outputs the operation signal OP-CMD, the row address RADD, the page buffer control signals PBSIGNALS, and the allowable bit VRY-BIT<#> in response to receiving the command CMD and the address ADD to control the peripheral circuits 200. In addition, the control logic 300 determines whether the verify operation passed or failed in response to receiving the pass or fail signal PASS/FAIL.

The control logic 300 may control the peripheral circuits 200 to perform the program operation or the erase operation on the selected memory block among the plurality of memory blocks MB1 through MBk included in the memory cell array 100.

The control logic 300 controls the peripheral circuits 200 to perform the copyback operation including programming the valid data stored in the selected memory block into another memory block, referred to as a target memory block, and controls the peripheral circuits 200 to perform the overwrite operation including programming the memory cells included in the selected memory block to a threshold voltage greater than the predetermined value after performing the copyback operation.

The control logic 300 includes an overwrite manager 310 that controls the copyback operation and the overwrite operation on the selected memory block. The overwrite manager 310 establishes the quantity of valid data among the data stored in the selected memory block and controls the peripheral circuits 200 to perform the copyback operation and the overwrite operation on the selected memory block when the checked quantity of valid data is less than the predetermined value.

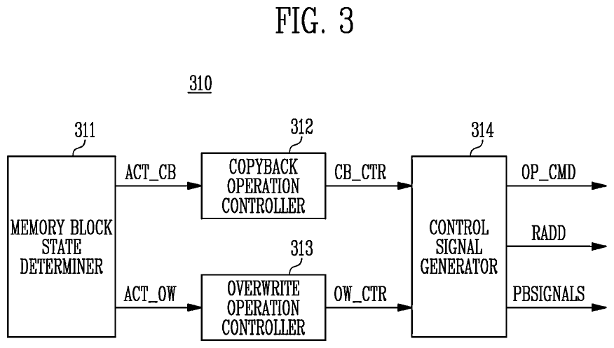

FIG. 3 is a diagram illustrating the overwrite manager, for example, as shown in FIG. 2.

Referring to FIG. 3, the overwrite manager 310 includes a memory block state determiner 311, a copyback operation controller 312, an overwrite operation controller 313, and a control signal generator 314.

The memory block state determiner 311 determines whether the selected memory block qualifies as an overwrite operation object memory block based on the quantity of valid data among the data stored in the selected memory block in an embodiment. For example, when the quantity of valid data among the data stored in the selected memory block is less than the predetermined value, the memory block state determiner 311 determines or identifies the selected memory block as an overwrite operation object memory block. When the quantity of valid data among the data stored in the selected memory block is equal to or greater than the predetermined value, the memory block state determiner 311 determines or identifies the selected memory block as a memory block other than an overwrite operation object memory block.

In another embodiment, the memory block state determiner 311 determines or identifies the selected memory block as an overwrite operation object memory block based on a ratio of the valid data among the entire data stored in the selected memory block. For example, when the ratio of the valid data among the entire data stored in the selected memory block is less than a predetermined ratio value, the memory block state determiner 311 determines or identifies the selected memory block as an overwrite operation object memory block. When the ratio of the valid data among the entire data stored in the selected memory block is equal to or greater than the predetermined ratio value, the memory block state determiner 311 determines or identifies the selected memory block as a memory block other than an overwrite operation object memory block.

For example, the memory block state determiner 311 may calculate the quantity of valid data or the ratio of valid data of the selected memory block by counting the quantity of pages in which the valid data is stored among a plurality of pages included in the selected memory block.

When the selected memory block is determined or identified as an overwrite operation object memory block and at least one valid data exists or is stored in the selected memory block, the memory block state determiner 311 generates and outputs a copyback activation signal ACT-CB and an overwrite activation signal ACT-OW.

When the selected memory block is determined or identifies as an overwrite operation object memory block and valid data is not stored in the selected memory block, the memory block state determiner 311 deactivates the copyback activation signal ACT-CB and generates and outputs only the overwrite activation signal ACT-OW. Accordingly, the copyback operation is not performed on the selected memory block.

In response to receiving the copyback activation signal ACT-CB, the copyback operation controller 312 generates and outputs a copyback control signal CB-CTR corresponding to a read operation on the valid data stored in the selected memory block and a valid data program operation including storing the read valid data in a memory block other than the selected memory block.

The overwrite operation controller 313 generates and outputs an overwrite control signal OW-CTR corresponding to the overwrite operation of increasing the threshold voltage value of the memory cells included in the selected memory block to at least the predetermined threshold voltage value in response to the overwrite activation signal ACT-OW.

In response to the copyback control signal, the control signal generator 314 generates the operation signal OP-CMD, the row address RADD, and the page buffer control signals PBSIGNALS and outputs the operation signal OP-CMD, the row address RADD, and the page buffer control signals PBSIGNALS to the peripheral circuits 200 of FIG. 2 to perform the read operation on the valid data stored in the selected memory block and the valid data program operation including storing the read valid data in the memory block other than the selected memory block.

In response to the overwrite control signal OW-CTR, the control signal generator 314 generates the operation signal OP-CMD, the row address RADD, and the page buffer control signals PBSIGNALS and outputs the operation signal OP-CMD, the row address RADD, and the page buffer control signals PBSIGNALS to the peripheral circuits 200 of FIG. 2 to perform the overwrite operation including increasing the threshold voltage value of the memory cells included in the selected memory block to at least the predetermined threshold voltage value.

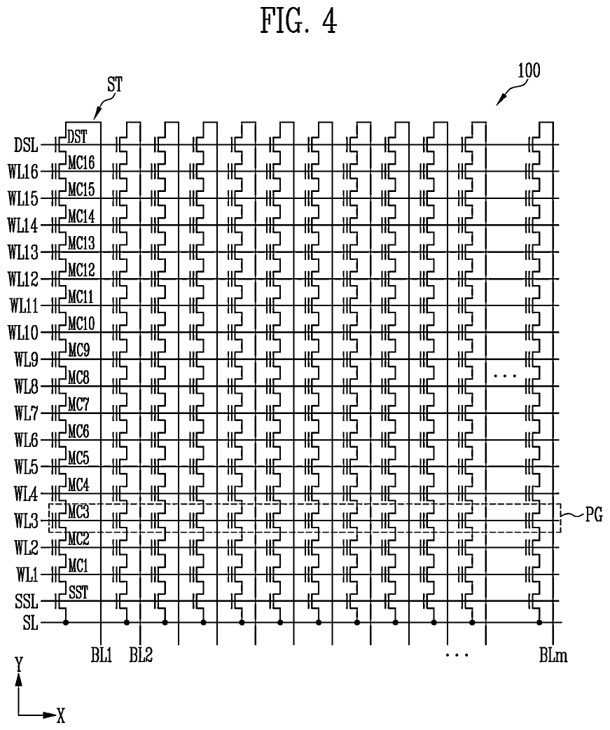

FIG. 4 is a diagram illustrating the memory block, for example, as shown in FIG. 2.

Referring to FIG. 4, a plurality of word lines arranged in parallel with each other between the first select line and the second select line are connected to the memory block. In this example, the first select line is a source select line SSL, and the second select line is a drain select line DSL. The memory block includes a plurality of memory strings ST connected between the bit lines BL1 through BLm and a source line SL. The bit lines BL1 through BLm are each connected to a different one of the memory strings ST, and the source line SL is commonly connected to the memory strings ST. Because each of the memory strings ST is similarly configured, one memory string ST connected to a first bit line BL1 is described as an example.

The memory string ST includes a source select transistor SST, a plurality of memory cells MC1 through MC16, and a drain select transistor DST connected in series between the source line SL and the first bit line BL1. One memory string ST may include at least one source select transistor SST and at least one drain select transistor DST, and may include more memory cells than the memory cells MC1 through MC16 shown in the figure.

A source of the source select transistor SST is connected to the source line SL, and a drain of the drain select transistor DST is connected to the first bit line BL1. The memory cells MC1 through MC16 are connected in series between the source select transistor SST and the drain select transistor DST. Gates of the source select transistors SST included in different memory strings ST are connected to the source select line SSL, gates of the drain select transistors DST included in different memory strings ST are connected to the drain select line DSL, and gates of the memory cells MC1 through MC16 are connected to a different one of the plurality of word lines WL1 through WL16. A group of the memory cells connected to the same word line among the memory cells included in different memory strings ST may be referred to as a page PG. The memory block includes the same quantity of pages PG as the quantity of word lines WL1 through WL16 in this example.

Each of the memory cells MC1 through MC16 may be configured as a single level cell (SLC) storing one data bit, a multi-level cell (MLC) storing two data bits, a triple level cell (TLC) storing three data bits, or a quad level cell (QLC) capable of storing four data bits.

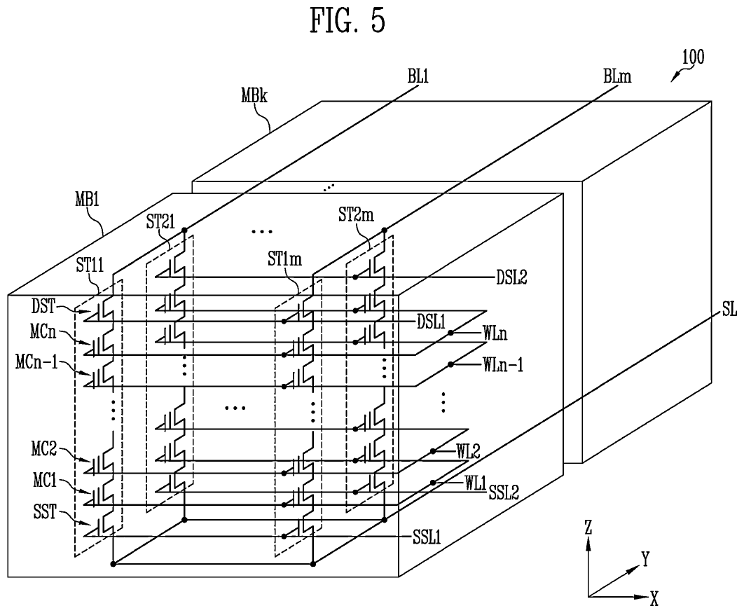

FIG. 5 is a diagram illustrating an embodiment of a memory block configured in a three-dimensional (3D) structure.

Referring to FIG. 5, the memory cell array 100 may include a plurality of memory blocks MB1 through MBk. In FIG. 5, for simplicity of description and the drawing, an internal configuration of a first memory block MB1 is shown, and an internal configuration of the remaining memory blocks MB2 to MBk is omitted. Second to k-th memory blocks MB2 to MBk are advantageously configured similarly to the first memory block MB1.

The first memory block MB1 includes a plurality of memory strings ST11 through ST1m and ST21 through ST2m. Each of the plurality of memory strings ST11 through ST1m and ST21 through ST2m extends along a vertical direction (, for example, the Z direction) relative to the orientation of FIG. 5. In the first memory block MB1, m memory strings are arranged in a row direction (for example, the X direction). In FIG. 5, two memory strings are arranged in a column direction (for example, the Y direction) for convenience of description, although three or more memory strings may be arranged in the column direction (Y direction).

Each of the plurality of memory strings ST11 through ST1m and ST21 through ST2m includes at least one source select transistor SST, a first memory cell MC1 through an n-th memory cells MCn, and at least one drain select transistor DST.

The source select transistor SST of each memory string is connected between the source line SL and the memory cells MC1 through MCn. The source select transistors of the memory strings arranged in the same row are connected to the same source select line. For example, the source select transistors of the memory strings ST11 through ST1m arranged in a first row are connected to a first source select line SSL1. The source select transistors of the memory strings ST21 through ST2m arranged in a second row are connected to a second source select line SSL2. As another embodiment, the source select transistors of the memory strings ST11 through ST1m and ST21 through ST2m are commonly connected to one source select line.

The first memory cell MC1 through the n-th memory cell MCn of each memory string are connected to each other in series between the source select transistor SST and the drain select transistor DST. Gates of the first memory cell MC1 through the n-th memory cell MCn are connected to the first word line WL1 through the n-th word line WLn, respectively.

In an embodiment, at least one of the memory cells MC1 through MCn is used as a dummy memory cell. When the dummy memory cell is provided, a voltage or a current of a corresponding memory string is stably controlled. Accordingly, reliability of data stored in the memory block MB1 may be improved.

The drain select transistor DST of each memory string is connected between the bit line and the memory cells MC1 through MCn. The drain select transistors DST of the memory strings arranged in the row direction are connected to the drain select line extending in the row direction. For example, the drain select transistors DST of the memory strings ST11 through ST1m of the first row are connected to a first drain select line DSL1. The drain select transistors DST of the memory strings ST21 through ST2m of the second row are connected to a second drain select line DSL2 in another example.

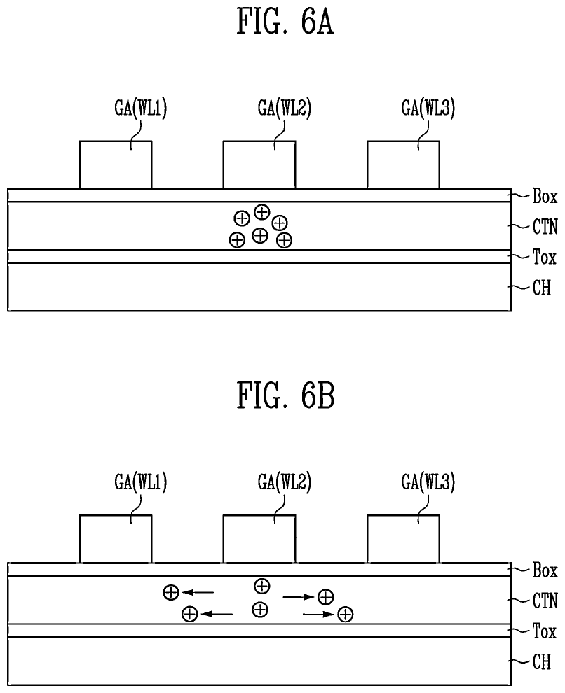

FIG. 6A, FIG. 6B, FIG. 6C, FIG. 6D, and FIG. 6E are diagrams illustrating a threshold voltage decrease phenomenon of memory cells by a hole existing in a region between memory cells.

Referring to FIG. 6A, among memory cells including a channel CH, a tunnel insulating layer Tox, a charge storage layer CTN, a blocking insulating layer Box, and a gate electrode GA, when a memory cell corresponding to a second word line WL2 is in the erase state or the program state in which the threshold voltage distribution is relatively low, a plurality of holes+are included in the charge storage layer CTN.

Referring to FIG. 6B, when a quantity of holes+included in the charge storage layer CTN of the memory cell programmed in the erase state or the program state in which the threshold voltage distribution is relatively low, the quantity of holes+spreads in the directions of adjacent memory cells or word lines over time. Accordingly, some holes+become positioned inside the charge storage layer CTN between the memory cells.

Referring to FIG. 6C, when the memory cell corresponding to the second word line WL2 is programmed into a relatively high program state among the plurality of program states, electrons-of the channel CH become trapped in the charge storage layer CTN of the memory cell corresponding to the second word line WL2 due to tunneling along the tunnel insulating layer Tox.

Referring to FIG. 6D, a quantity of electrons-included in the charge storage layer CTN of the memory cell corresponding to the second word line WL2 spreads to the charge storage layer CTN between the memory cells toward the holes+existing inside the charge storage layer CTN between the memory cells, and the electrons−and the holes+spreading in the charge storage layer CTN between the memory cells combine, as denoted by the arrows.

Referring to FIG. 6E, the quantity of electrons-trapped in the charge storage layer CTN of the memory cell corresponding to the second word line WL2 decreases due to the electrons−spreading through the charge storage layer CTN between the memory cells, and as a result, the threshold voltage of the memory cell corresponding to the second word line WL2 decreases.

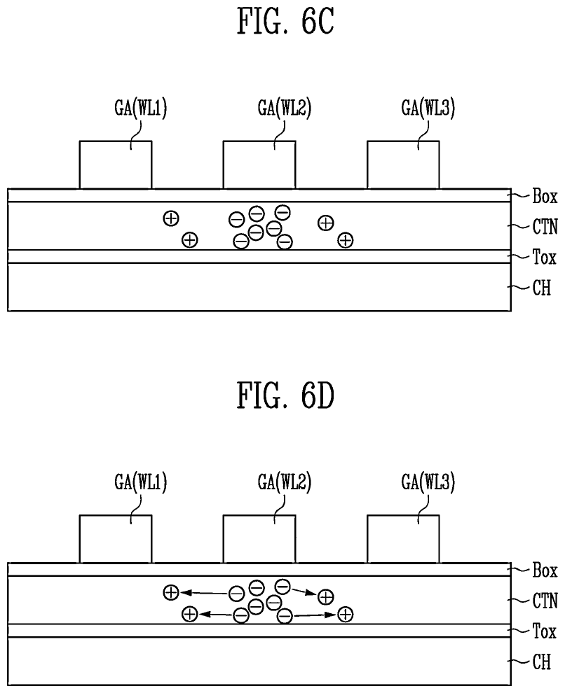

FIG. 7 is a diagram illustrating a threshold voltage distribution according to a retention characteristic decrease of programmed memory cells.

In an embodiment of the present disclosure, a threshold voltage distribution of memory cells programmed in an MLC method is described.

Referring to FIG. 7, the memory cells included in the selected memory block are programmed into an erase state E and a plurality of program states P1, P2, and P3. For example, a threshold voltage of memory cells of the erase state E is lower than 0V, and a threshold voltage of memory cells programmed into the first program state P1 is higher than a first read voltage R1 and lower than a second read voltage R2. A threshold voltage of memory cells programmed into the second program state P2 is higher than the second read voltage R2 and lower than a third read voltage R3, and a threshold voltage of memory cells programmed into the third program state P3 is higher than the third read voltage R3.

In memory cells programmed into at least one program state of which a threshold voltage distribution is relatively high, for example, the second program state P2 and the third program state P3, as shown in FIG. 6A, FIG. 6B, FIG. 6C, FIG. 6D and FIG. 6E described above, the trapped electrons spread in the directions of the adjacent memory cells, and as a result, the threshold voltage distribution is decreased. According to this example, the threshold voltage distribution of some of the memory cells programmed into the second program state P2 is lower than the second read voltage R2, the threshold voltage distribution of some of the memory cells programmed into the third program state P3 is lower than the third read voltage R3, and as a result, reliability of data stored in the programmed memory block is decreased.

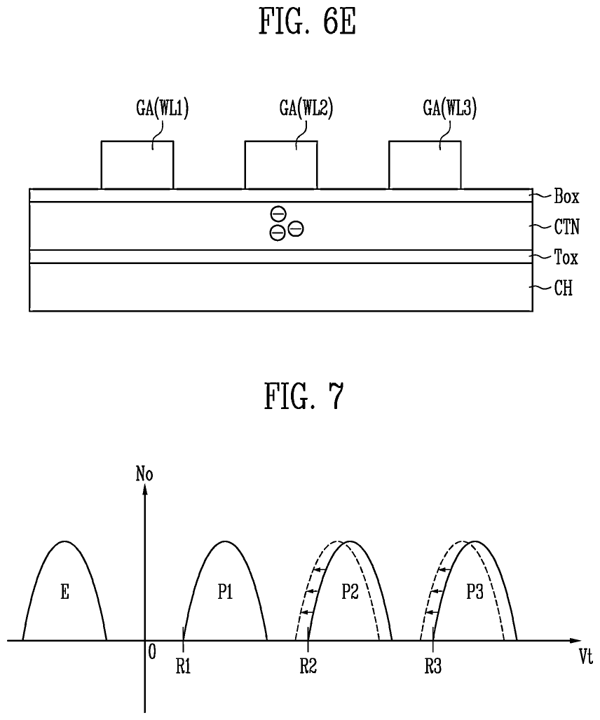

FIG. 8 is a flowchart illustrating a method of operating a memory device according to an embodiment of the present disclosure.

With reference to FIG. 2 through FIG. 8, a method of operating a memory device according to an embodiment of the present disclosure is described as follows.

The memory device 1100 counts S810 the quantity of valid data of the selected memory block.

The memory device 1100 may perform a background operation on a selected memory block (for example, MB1). For example, the background operation may be a read reclaim, garbage collection, or read refresh operation.

After performing any background operation on the selected memory block MB1, the memory device 1100 counts the quantity of valid data among the data stored in the selected memory block MB1.

The memory block state determiner 311 of the overwrite manager 310 counts the quantity of valid data among the data stored in the selected memory block MB1. The memory block state determiner 311 determines whether the selected memory block MB1 qualifies as an overwrite operation object memory block based on the counted quantity of valid data of the selected memory block MB1. For example, when the quantity of valid data of the selected memory block MB1 is less than the predetermined value, the memory block state determiner 311 determines or identifies the selected memory block MB1 as an overwrite operation object memory block. When the quantity of valid data among the data stored in the selected memory block MB1 is equal to or greater than the predetermined value, the memory block state determiner 311 determines or identifies the selected memory block MB1 as a memory block other than an overwrite operation object memory block.

In another embodiment, the memory block state determiner 311 determines or identifies whether the selected memory block MB1 qualifies as an overwrite operation object memory block based on the ratio of the valid data among the entire data stored in the selected memory block MB1. For example, when the ratio of the valid data among the entire data stored in the selected memory block MB1 is less than the predetermined ratio value, the memory block state determiner 311 determines or identifies the selected memory block MB1 as an overwrite operation object memory block. When the ratio of the valid data among the entire data stored in the selected memory block MB1 is equal to or greater than the predetermined ratio value, the memory block state determiner 311 determines or identifies the selected memory block as a memory block other than an overwrite operation object memory block.

When the selected memory block is determined or identified as an overwrite operation object memory block and at least one valid data is stored in the selected memory block, the memory block state determiner 311 generates and outputs the copyback activation signal ACT-CB and the overwrite activation signal ACT-OW.

When the selected memory block MB1 is determined or identified as an overwrite operation object memory block and valid data is not stored in the selected memory block, or only invalid data is stored in the selected memory block, the memory block state determiner 311 generates and outputs only the overwrite activation signal ACT-OW without generation of the copyback activation signal ACT-CB. The copyback activation signal ACT-CB may be deactivated by not generating the copyback activation signal ACT-CB, blocking generation of the copyback activation signal ACT-CB, or blocking the generated copyback activation signal ACT-CB from being received.

The memory device 1100 programs S820 the valid data of the selected memory block MB1 into a target memory block (for example, MB2). The target memory block may be, for example, any of the memory blocks of the memory device 1100 other than the selected memory block MB1.

When the selected memory block MB1 is identified as an overwrite operation object memory block by the memory block state determiner 311, the peripheral circuits 200 perform the copyback operation including reading the valid data stored in the selected memory block MB1 and programming the read valid data into the target memory block MB2.

For example, the copyback operation controller 312 of the overwrite manager 310 generates and outputs the copyback control signal CB-CTR corresponding to the read operation on the valid data stored in the selected memory block MB1 and the valid data program operation including storing the read valid data in the target memory block MB2 in response to the copyback activation signal ACT-CB. The target memory block may not be the selected memory block MB1. In response to the copyback control signal CB-CTR, the control signal generator 314 generates the operation signal OP-CMD, the row address RADD, and the page buffer control signals PBSIGNALS to perform the read operation on the valid data stored in the selected memory block MB1. The peripheral circuits 200 read the valid data stored in the selected memory block MB1 in response to the operation signal OP-CMD, the row address RADD, and the page buffer control signals PBSIGNALS.

In response to the copyback control signal CB-CTR, the control signal generator 314 generates the operation signal OP-CMD, the row address RADD, and the page buffer control signals PBSIGNALS to perform the program operation including storing the read valid data in the target memory block MB2. The peripheral circuits 200 program the read valid data into the target memory block MB2 in response to the operation signal OP-CMD, the row address RADD, and the page buffer control signals PBSIGNALS.

When the memory block MB1 selected is identified as an overwrite operation object memory block by the memory block state determiner 311, but no valid data is stored in the selected memory block MB1, the copyback operation is not performed on the selected memory block MB1.

The memory device 1100 performs S830 the overwrite operation on the selected memory block MB1.

During the overwrite operation, memory cells of the selected memory block MB1 on which the background operation and the copyback operation are performed are programmed into the erase state E and the plurality of program states P1, P2, and P3.

The overwrite operation controller 313 of the overwrite manager 310 generates and outputs the overwrite control signal OW-CTR corresponding to the overwrite operation of the selected memory block MB1 in response to the overwrite activation signal ACT-OW.

In response to the overwrite control signal OW-CTR, the control signal generator 314 outputs the operation signal OP-CMD, the row address RADD, and the page buffer control signals PBSIGNALS to the peripheral circuits 200 to perform the overwrite operation including increasing the threshold voltage value of the memory cells included in the selected memory block MB1 to at least the predetermined threshold voltage value.

For example, in response to the operation signal OP-CMD, the voltage generation circuit 210 generates and output the program voltage, and the row decoder 220 transmits or transfers the program voltage to a word of the selected memory block MB1 based on the row address RADD. In addition, the page buffer group 230 applies a program allowable voltage (for example, a ground voltage) to the bit lines BL1 through BLm in response to the page buffer control signals PBSIGNALS.

The overwrite operation may be performed in an SLC program method, an MLC program method, a TLC program method, or a QLC program method.

The overwrite operation is a program operation including increasing the threshold voltage of memory cells in the erase state E among the memory cells included in the selected memory block MB1 to at least the predetermined threshold voltage value.

During the overwrite operation, the voltage generation circuit 210 generates an overwrite program voltage that selectively increases only the threshold voltage of the memory cells that are in the erase state E. The voltage generation circuit 210 generates the overwrite program voltage a predetermined quantity of instances, and the row decoder 220 applies the overwrite program voltage to the selected word line or all word lines the predetermined quantity of instances. In another embodiment, the voltage generation circuit 210 generates the overwrite program voltage during a predetermined time, and the row decoder 220 applies the overwrite program voltage to the selected word lines or all word lines during a predetermined application time.

In another embodiment, the overwrite operation is a program operation including increasing the threshold voltage of the memory cells in the erase state E and at least one program state among the memory cells included in the selected memory block MB1 to at least the predetermined threshold voltage value. At least one program state may be the first program state P1 in which the threshold voltage distribution is the lowest among the plurality of program states, for example, P1, P2, and P3.

During the overwrite operation, after applying the overwrite program voltage to the selected word line or all word lines of the selected memory block MB1, a verify operation, including establishing whether the threshold voltage value of the memory cells included in the selected memory block MB1 is equal to or greater than the predetermined threshold voltage value, need not be performed on the selected memory block MB1.

The operation S810, S820, and S830 of the memory device 1100 described above may be performed immediately after the background operation of the selected memory block, and in another embodiment, the operation S810, S820, and S830 of the memory device 1100 described above may be performed when the memory device 1100 is in an idle state.

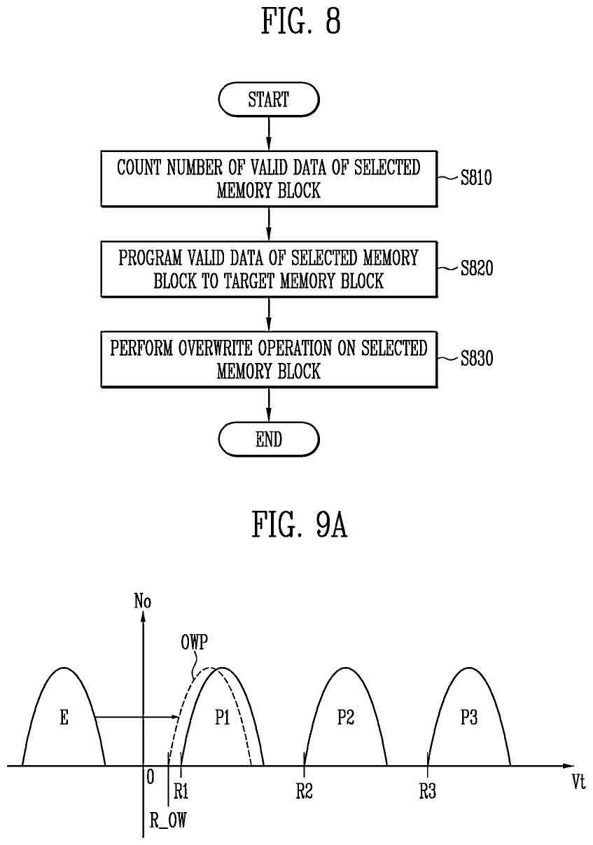

FIG. 9A is a diagram illustrating a threshold voltage distribution of memory cells during an overwrite operation of a memory device according to an embodiment of the present disclosure.

Referring to FIG. 9A, among the plurality of memory cells included in the selected memory block, memory cells in the erase state E are selectively programmed into an overwrite state OWP.

The plurality of memory cells are at the threshold voltage value corresponding to the erase state E and the plurality of program states P1, P2, and P3. For example, the threshold voltage of the memory cells of the erase state E are lower than 0V, and the threshold voltage of the memory cells programmed into the first program state P1 is higher than the first read voltage R1 and lower than the second read voltage R2. In addition, the threshold voltage of the memory cells programmed into the second program state P2 is higher than the second read voltage R2 and lower than the third read voltage R3, and the threshold voltage of the memory cells programmed into the third program state P3 is higher than the third read voltage R3.

During the overwrite operation, the memory cells corresponding to the erase state E among the plurality of memory cells are selectively programmed to increase the threshold voltage. Accordingly, the threshold voltage of the memory cells corresponding to the erase state E increases to the overwrite state OWP. The overwrite state OWP has a threshold voltage distribution greater than an overwrite reference voltage R-OW. The overwrite reference voltage R-OW may be greater than 0V.

The memory cells included in the selected memory block of the memory cells in the erase state E in which holes exist in the charge storage layer are programmed into the overwrite state OWP by the overwrite operation. Accordingly, a phenomenon that holes spreading to a region between the memory cells as shown in FIG. 6B is prevented. Therefore, a problem where threshold voltage distribution is decreased during a subsequent program operation of the selected memory block may be reduced.

FIG. 9B is a diagram illustrating a threshold voltage distribution of memory cells during an overwrite operation of a memory device according to another embodiment of the present disclosure.

Referring to FIG. 9B, among the plurality of memory cells included in the selected memory block, memory cells in the erase state E and at least one program state (for example, P1) are selectively programmed into the overwrite state OWP.

The plurality of memory cells are at the threshold voltage value corresponding to the erase state E and the plurality of program states P1, P2, and P3. For example, the threshold voltage of the memory cells of the erase state E is lower than 0V, and the threshold voltage of the memory cells programmed into the first program state P1 is higher than the first read voltage R1 and lower than the second read voltage R2. In addition, the threshold voltage of the memory cells programmed into the second program state P2 is higher than the second read voltage R2 and lower than the third read voltage R3, and the threshold voltage of the memory cells programmed into the third program state P3 is higher than the third read voltage R3.

During the overwrite operation, the memory cells corresponding to the erase state E and the first program state P1 in which the threshold voltage distribution is relatively low are selectively programmed to increase the threshold voltage. Accordingly, the threshold voltage of the memory cells corresponding to the erase state E and the first program state P1 increases to the overwrite state OWP. The overwrite state OWP has the threshold voltage distribution greater than the overwrite reference voltage R-OW. The overwrite reference voltage R-OW may be greater than 0V.

The memory cells included in the selected memory block, the memory cells in the erase state E and the first program state P1 in which holes exist in the charge storage layer, are programmed into the overwrite state OWP by the overwrite operation. Accordingly, a phenomenon that holes spreading to a region between the memory cells as shown in FIG. 6B described above is prevented. Therefore, a problem where threshold voltage distribution is decreased during a subsequent program operation of the selected memory block may be reduced.

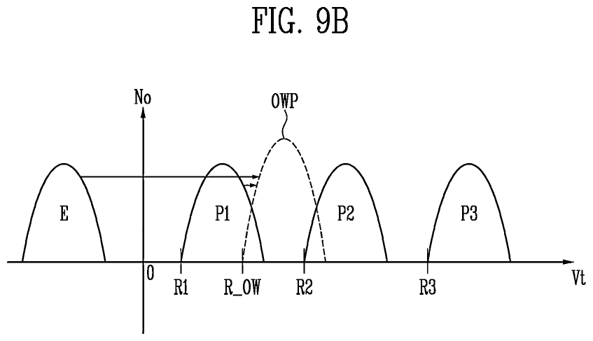

FIG. 10 is a diagram illustrating another embodiment of the memory system including the memory device, for example, as shown in FIG. 2.

Referring to FIG. 10, the memory system 3000 may be a cellular phone, a smart phone, a tablet PC, a personal digital assistant (PDA) a wireless communication device, and so forth. The memory system 3000 includes the memory device 1100 and the memory controller 1200 capable of controlling the operation of the memory device 1100. The memory controller 1200 controls data access operations, for example, a program operation, an erase operation, and a read operation, of the memory device 1100 under control of a processor 3100. The memory device 1100 in conjunction with the memory controller 1200 perform the copyback operation and the overwrite operation described above.

Data programmed in the memory device 1100 may be output through a display 3200 under the control of the memory controller 1200.

A radio transceiver 3300 transmits and receives radio signals through an antenna ANT. For example, the radio transceiver 3300 converts radio signals received through the antenna ANT into signal processed by the processor 3100. The processor 3100 processes the signals from the radio transceiver 3300 and transfers the processed signals, for example, to the memory controller 1200 or the display 3200. The memory controller 1200 may provide the signals processed by the processor 3100 to the memory device 1100. The radio transceiver 3300 converts signals output from the processor 3100 into radio signals and transmits the converted radio signals to an external device through the antenna ANT. An input device 3400 is a device that inputs control signals that control the operation of the processor 3100 or data to be processed by the processor 3100. The input device 3400 may be a pointing device such as a touch pad or a computer mouse, a keypad, a keyboard, and so forth. The processor 3100 controls the operation of the display 3200 such that data output from the memory controller 1200, data output from the radio transceiver 3300, and data output from the input device 3400 are output via the display 3200.

According to an embodiment, the memory controller 1200 capable of controlling the operation of memory device 1100 may be part of the processor 3100 or an integrated circuit chip separate from the processor 3100.

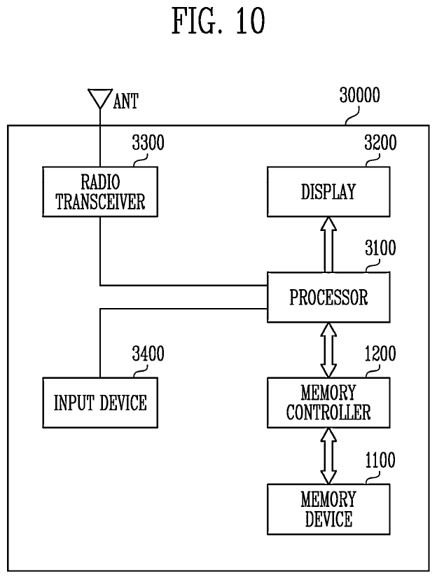

FIG. 11 is a diagram illustrating another embodiment of the memory system including the memory device, for example, as shown in FIG. 2.

Referring to FIG. 11, the memory system 4000 may be a personal computer (PC), a tablet PC, a net-book, an e-reader, a personal digital assistant (PDA), a portable multimedia player (PMP), an MP3 player, an MP4 player, and so forth.

The memory system 4000 includes the memory device 1100 and the memory controller 1200 capable of controlling the data processing operation of the memory device 1100. The memory device 1100 performs data access operations, for example, a program operation, an erase operation, and a read operation, under control of the memory controller 1200. The memory device 1100 in conjunction with the memory controller 1200 perform the copyback operation and the overwrite operation described above.

A processor 4100 outputs data stored in the memory device 1100 via a display 4300 according to data input through an input device 4200. For example, the input device 4200 may be a pointing device such as a touch pad or a computer mouse, a keypad, a keyboard, and so forth.

The processor 4100 controls the overall operation of the memory system 4000 and controls the operation of the memory controller 1200. The memory controller 1200 capable of controlling the operation of memory device 1100 may be a part of the processor 4100 or an integrated circuit chip separate from the processor 4100.

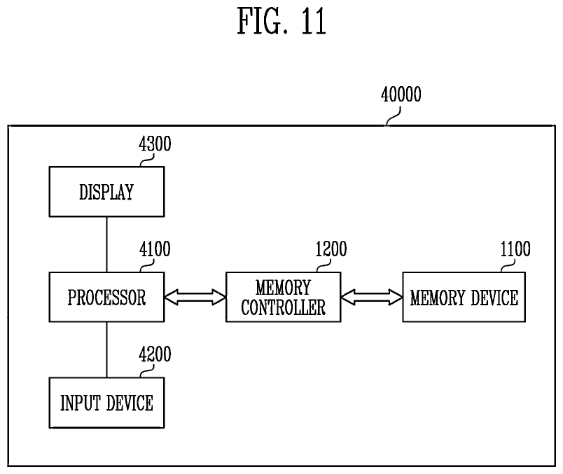

FIG. 12 is a diagram illustrating another embodiment of the memory system including the memory device, for example, as shown in FIG. 2.

Referring to FIG. 12, the memory system 5000 may be an image processing device, for example, a digital camera, a portable phone including a digital camera, a smart phone including a digital camera, a tablet PC including a digital camera, and so forth.

The memory system 5000 includes the memory device 1100 and the memory controller 1200 capable of controlling the data processing operations, for example, a program operation, an erase operation, and a read operation, of the memory device 1100. The memory device 1100 in conjunction with the memory controller 1200 perform the copyback operation and the overwrite operation described above.

An image sensor 5200 of the memory system 5000 converts an optical image into digital signals. The converted digital signals are transmitted or transferred to a processor 5100 or the memory controller 1200. Under control of the processor 5100, the digital signals may be output via a display 5300 or stored in the memory device 1100 through the memory controller 1200. The data stored in the memory device 1100 may be output via the display 5300 under control of the processor 5100 or the memory controller 1200.

According to an embodiment, the memory controller 1200 capable of controlling the operation of memory device 1100 may be a part of the processor 5100 or may be an integrated circuit chip separate from the processor 5100.

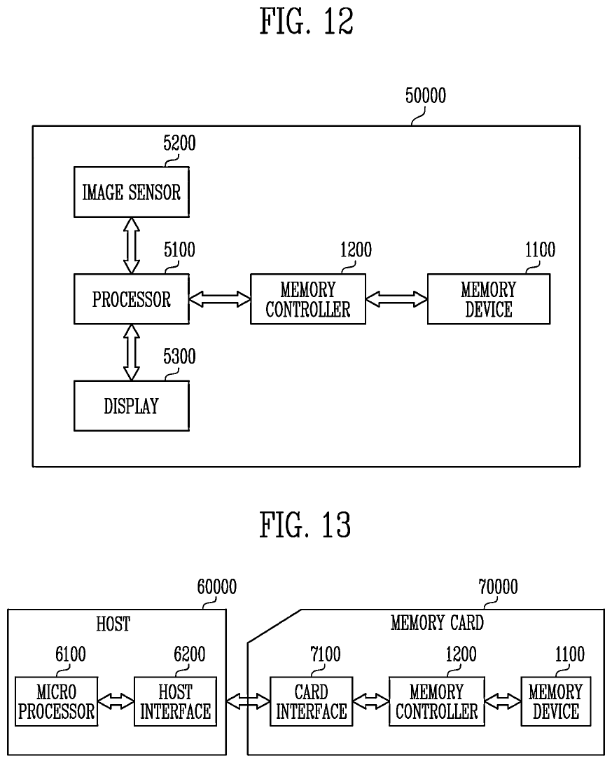

FIG. 13 is a diagram illustrating another embodiment of the memory system including the memory device, for example, as shown in FIG. 2.

Referring to FIG. 13, the memory system 7000 may be a memory card or a smart card. The memory system 7000 includes the memory device 1100, the memory controller 1200, and a card interface 7100.

The memory device 1100 performs data access operations, for example, a program operation, an erase operation, and a read operation, under control of the memory controller 1200. The memory device 1100 in conjunction with the memory controller 1200 perform the copyback operation and the overwrite operation described above.

The memory controller 1200 controls data exchange between the memory device 1100 and the card interface 7100. The card interface 7100 may be, but is not limited to, a secure digital (SD) card interface or a multi-media card (MMC) interface.

The card interface 7100 provides an interface for data exchange between a host 6000 and the memory controller 1200 according to a protocol of the host 6000. The card interface 7100 may support a universal serial bus (USB) protocol, an interchip (IC)-USB protocol, and so forth. In this example, the card interface may refer to hardware capable of supporting a protocol used by the host 6000, software installed in the hardware, and/or a signal transmission method.

When the memory system 7000 is connected to a host interface 6200 of the host 6000 such as a PC, a tablet PC, a digital camera, a digital audio player, a mobile or cellular phone, a console video game hardware, a digital set-top box, and so forth, the host interface 6200 performs data communication with the memory device 1100 through the card interface 7100 and the memory controller 1200 under control of a microprocessor 6100.

Although specific embodiments are described in the detailed description, various changes are possible that do not deviate from the scope and spirit of the present disclosure. Therefore, the scope of the present disclosure should not be limited to the above-described embodiments. All changes within the meaning and range of equivalency of the claims are to be included within their scope.

What is claimed is:

1. A memory device comprising:
a plurality of memory blocks each including a plurality of memory cells;
peripheral circuits configured to perform a background operation and an overwrite operation on a selected memory block among the plurality of memory blocks; and
control logic configured to control the peripheral circuits to perform the background operation and the overwrite operation,
wherein the control logic controls the peripheral circuits to perform the overwrite operation including increasing a threshold voltage of the plurality of memory cells of the selected memory block to at least a predetermined threshold voltage value based on the quantity of valid data stored in the selected memory block.

2. The memory device of claim 1, wherein the control logic further comprises an overwrite manager configured to establish the quantity of valid data stored in the selected memory block and, when the established quantity of valid data is less than a predetermined value, to control the peripheral circuits to perform a copyback operation and the overwrite operation on the selected memory block.

3. The memory device of claim 2, wherein the overwrite manager comprises:
a memory block state determiner configured to count the quantity of valid data stored in the selected memory block, determine whether the selected memory block qualifies as an overwrite operation object memory block based on the counted quantity of valid data, generate a copyback activation signal and an overwrite activation signal, and output the copyback activation signal and the overwrite activation signal;
a copyback operation controller configured to generate and output a copyback control signal corresponding to a copyback operation including a read operation on the valid data stored in the selected memory block and a valid data program operation including storing the read valid data in a target memory block other than the selected memory block among the plurality of memory blocks in response to the copyback activation signal;
an overwrite operation controller configured to generate and output an overwrite control signal corresponding to the overwrite operation on the selected memory block in response to the overwrite activation signal; and
a control signal generator configured to generate control signals for controlling the peripheral circuits in response to at least one of the copyback control signal and the overwrite control signal.

4. The memory device of claim 1, further comprising a memory block state determiner configured to count the quantity of valid data stored in the selected memory block, wherein the memory block state determiner identifies the selected memory block as an overwrite operation object memory block when the quantity of valid data stored in the selected memory block is less than a predetermined value, and when valid data is not stored in the selected memory block, deactivating a copyback activation signal corresponding to a copyback operation.

5. The memory device of claim 3, wherein the memory state determiner counts the quantity of valid data by counting the quantity of pages in which the valid data is stored among a plurality of pages included in the selected memory block.

6. The memory device of claim 1, wherein the peripheral circuits apply an overwrite program voltage to a selected word line or all word lines of the selected memory block during the overwrite operation.

7. The memory device of claim 1, wherein the peripheral circuits increase the threshold voltage of memory cells corresponding to an erase state among the plurality of memory cells included in the selected memory block to at least the predetermined threshold voltage value during the overwrite operation.

8. The memory device of claim 1, wherein the peripheral circuits increase the threshold voltage of memory cells corresponding to an erase state and at least one program state among the plurality of memory cells included in the selected memory block at least to the predetermined threshold voltage value during the overwrite operation.

9. The memory device of claim 8, wherein the at least one program state is a program state in which a threshold voltage distribution is relatively low among a plurality of program states.

10. The memory device of claim 1, wherein the predetermined threshold voltage value is greater than 0V.

11. A method of operating a memory device, the method comprising:
establishing the quantity of valid data stored in a selected memory block;
performing a copyback operation on the selected memory block when the quantity of valid data is less than a predetermined value; and
performing an overwrite operation on selected memory cells corresponding to an erase state, or the erase state and at least one program state, among memory cells included in the selected memory block.

12. The method of claim 11, wherein during the copyback operation, the valid data of the selected memory block is read and the read valid data is programmed into a target memory block other than the selected memory block.

13. The method of claim 11, further comprising performing the copyback operation in response to a copyback control signal when valid data is stored in the selected memory block.

14. The method of claim 11, wherein the overwrite operation increases a threshold voltage value of the selected memory cells to at least a predetermined threshold voltage value by applying an overwrite program voltage to a selected word line or all word lines of the selected memory block.

15. The method of claim 14, wherein the predetermined threshold voltage value is greater than 0V.

16. The method of claim 14, wherein the at least one program state is a program state in which a threshold voltage distribution is relatively low among a plurality of program states.

17. A method of operating a memory device, the method comprising:
establishing a quantity of valid data stored in a selected memory block on which a background operation is performed;
identifying the selected memory block as an overwrite operation object memory block based on the quantity of valid data;
performing a copyback operation including storing, in a target memory block, the valid data stored in the selected memory block; and
performing an overwrite operation including increasing a threshold voltage of selected memory cells corresponding to an erase state, or the erase state and at least one program state, among memory cells included in the selected memory block to at least a predetermined threshold voltage value after the copyback operation.

18. The method of claim 17, wherein identifying the selected memory block as an overwrite operation object memory block comprises determining whether the quantity of valid data stored in the selected memory block is less than a predetermined value.

19. The method of claim 17, wherein the overwrite operation increases a threshold voltage value of the selected memory cells to at least a predetermined threshold voltage value by applying an overwrite program voltage to a selected word line or all word lines of the selected memory block.

20. The method of claim 17, wherein the at least one program state is a program state in which a threshold voltage distribution is relatively low among a plurality of program states.

21. A method comprising:
establishing a quantity of valid data stored in a first memory block of a plurality of memory blocks;
when the quantity of valid data is less than a predetermined value, performing a copyback operation including storing, in a second memory block of the plurality of memory blocks, the valid data stored in the first memory block; and
performing an overwrite operation including increasing a threshold voltage of a plurality of memory cells of the first memory block to at least a predetermined threshold voltage value based on the quantity of valid data stored in the first memory block.
